(19) United States
(12) Patent Application Publication
(10) Pub. No.: US 2024/0222202 A1
(43) Pub. Date: Jul. 4, 2024

(54) Methods for measuring thickness and methods for manufacturing a device using the same

(71) Applicant: Samsung Electronics Co., Ltd., Suwon-si (KR)

(72) Inventors: Sangwon Park, Suwon-si (KR); Seunghak Park, Suwon-si (KR); Byeonghwan Son, Suwon-si (KR); Ayeong Cha, Suwon-si (KR)

(21) Appl. No.: 18/498,194

(22) Filed: Oct. 31, 2023

(30) Foreign Application Priority Data
Dec. 29, 2022 (KR) 10-2022-0188314

(51) Int. Cl. H01L 21/66; G01B 11/06; H01L 21/67

(52) U.S. Cl. CPC H01L 22/26; G01B 11/06; H01L 21/67253; H10B 41/27

(57) ABSTRACT

A method of manufacturing a device includes forming a first layer on a first substrate, the first layer for measuring a thickness thereof; irradiating the first layer with first light having a first wavelength that passes into the first layer; sensing first reflected light reflected from a bottom surface of the first layer; irradiating the first layer with second light having a second wavelength shorter than the first wavelength that reflects from the first layer; sensing second reflected light reflected from an upper surface of the first layer; obtaining first data corresponding to a first positional coordinate in a vertical direction of the bottom surface of the first layer from the first reflected light; obtaining second data corresponding to a second positional coordinate in the vertical direction of the upper surface of the first layer from the second reflected light; and obtaining skew data representing a thickness of the first layer using the first and second data.

### CROSS-REFERENCE TO RELATED APPLICATION

This application claims priority under 35 USC § 119 to Korean Patent Application No. 10-2022-0188314 filed on Dec. 29, 2022 in the Korean Intellectual Property Office (KIPO), the entire disclosure of which is incorporated herein by reference.

### BACKGROUND

### 1. Field

Embodiments of the present disclosure relate to a method for measuring a thickness, and more particularly, a method for measuring a thickness of a layer included in a semiconductor device using light.

### 2. Description of the Related Art

In the manufacture of a semiconductor device, a thickness of a layer (e.g., a photoresist layer) may be measured using light as non-destructive test. Pattern structures constituting the semiconductor device may be repeatedly formed on a substrate, and thus, upper surfaces of the pattern structures on the substrate may have a step difference. When a photoresist layer is formed on the pattern structures, the photoresist layer may have a difference in thickness depending on the horizontal position where the thickness is measured. In addition, a reflectivity of light from the photoresist layer formed on the pattern structures may be different according to the step height difference of the pattern structures. Therefore, it may be difficult to accurately measure a thickness of the photoresist layer on the pattern structures.

### SUMMARY

Example embodiments provide a method of accurately measuring a thickness of a layer such as a photoresist layer and for manufacturing a device.

According to embodiments of the present disclosure, a method of manufacturing a device may include forming a first layer on a first substrate, the first layer for measuring a thickness thereof; irradiating the first layer with first light having a first wavelength that passes into the first layer; sensing first reflected light reflected from a bottom surface of the first layer; irradiating the first layer with second light having a second wavelength shorter than the first wavelength that reflects from the first layer; sensing second reflected light reflected from an upper surface of the first layer; obtaining first data corresponding to a first positional coordinate in a vertical direction of the bottom surface of the first layer from the first reflected light; obtaining second data corresponding to a second positional coordinate in the vertical direction of the upper surface of the first layer from the second reflected light; obtaining skew data representing a thickness of the first layer using the first and second data; and forming one or more semiconductor devices with a second substrate including forming at least one layer on the second substrate using process conditions determined from the skew data.

According to embodiments of the present disclosure, a method of measuring a thickness may include forming a pattern structure on a sample substrate; forming a reflective layer conformally on an upper surface of the pattern structure; forming a photoresist layer on the reflective layer, the photoresist layer contacting the reflective layer; irradiating the photoresist layer with first light that passes into the first layer; sensing first reflected light reflected from an upper surface of the reflective layer; irradiating the photoresist layer with second light having a different wavelength from the first light; sensing second reflected light reflected from an upper surface of the photoresist layer; obtaining first data representing a first positional coordinate in a vertical direction of a bottom surface of the photoresist layer for each of a plurality of horizontal positions from the first reflected light; obtaining second data displayed as a map representing a positional coordinate in the vertical direction of the upper surface of the photoresist layer for the plurality of horizontal positions from the second reflected light; and obtaining skew data displayed as a map representing a thickness of the photoresist layer for each of the horizontal positions using the first and second data.

According to embodiments of the present disclosure, a method of measuring a thickness may include forming a pattern structure on a sample substrate, the pattern structure having varying heights of an upper surface depending on horizontal positions thereof; forming a reflective layer conformally on an upper surface of the pattern structure; forming a photoresist layer on the reflective layer, the photoresist layer contacting the reflective layer; irradiating the photoresist layer with first light; obtaining first data representing a position of a bottom surface of the photoresist layer from first reflected light, wherein the first reflected light is produced by the first light reflected from an upper surface of the reflective layer; irradiating the photoresist layer with second light; obtaining second data representing a position of an upper surface of the photoresist layer from second reflected light, wherein the second reflected light is produced by the second light reflected from an upper surface of the reflective layer; and obtaining skew data representing a thickness of the photoresist layer using the first and second data.

According to the semiconductor device of example embodiments, the thickness and the distribution of the thickness of a layer formed on pattern structures may be obtained at each of a plurality of horizontal positions. Processes for manufacturing the semiconductor device may be optimized using the thickness and the distribution of the thickness, so that a target semiconductor device may be manufactured.

### BRIEF DESCRIPTION OF THE DRAWINGS

FIG. 1 is a block diagram illustrating an apparatus for measuring a thickness of a layer according to example embodiments.

FIG. 2 is a flowchart illustrating a method for measuring a thickness of a first layer on pattern structures according to example embodiments.

FIGS. 3 to 6 and 8 are cross-sectional views illustrating a method of measuring a thickness of a first layer on pattern structures according to example embodiments.

FIGS. 7, 10 and 11 are data obtained using first light according to example embodiments.

FIGS. 9, 12 and 13 are data obtained using second light according to example embodiments.

FIG. 14 is data of a thickness of a first layer according to example embodiments.

FIGS. 15 to 27 are cross-sectional views illustrating a method for manufacturing a semiconductor device according to example embodiments.

### DETAILED DESCRIPTION OF THE EMBODIMENTS

Hereinafter, exemplary embodiments of the present disclosure will be described in detail with reference to the accompanying drawings.

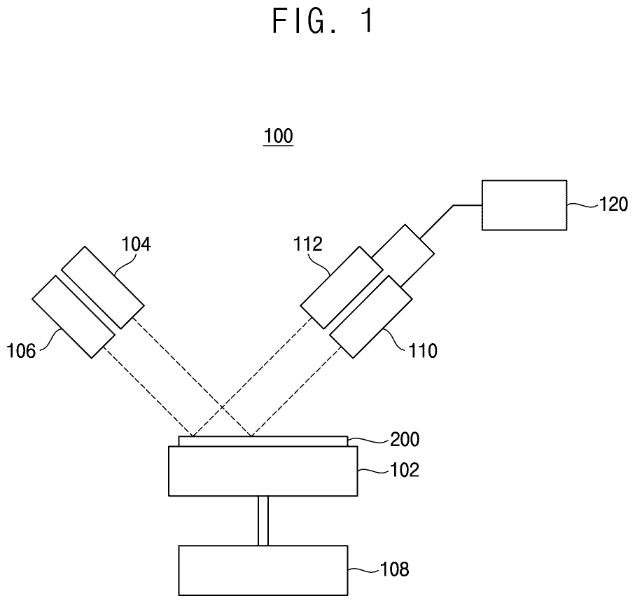

FIG. 1 is a block diagram illustrating an apparatus for measuring a thickness according to example embodiments.

Referring to FIG. 1, the apparatus for measuring a thickness 100 may include a stage 102, a first light irradiation unit 104, a second light irradiation unit 106, a drive 108, a first sensing unit 110 (e.g., a first sensor), a second sensing unit 112 (e.g., a second sensor) and a data processor 120.

A substrate 200 having a first layer in which the thickness is being measured may be loaded onto the stage 102 such that a front side of the substrate 200 faces an upper surface of the stage 102. The front side of the substrate 200 may be planar surface. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim). The term “substrate” denotes a stack structure including a base substrate on which layers may be formed, and predetermined layers or films formed on a surface of the substrate. In addition, the term “surface of a substrate” may denote an exposed surface of the substrate itself, or an external surface of a predetermined layer or a film formed on the substrate. The stage 102 may be connected to the drive 108, which is configured to move the stage 102. The drive 108 may receive a signal from a controller which may include data processor 120 and move the stage 102 according to the signal. The drive 108 may include multiple actuators configured to move the stage 102 along multiple axes such as the X axis and the Y axis which form a horizontal plane which may be parallel to an upper surface of the stage 102 and/or bottom surface of the substrate, and the Z axis which may also be referred to as a vertical direction and may be perpendicular to the upper surface of the stage 102, an upper surface of the substrate, and/or the bottom surface of the substrate. The substrate 200 may include die regions on which individual chips may be formed. A pattern structure may be formed on the substrate 200, and the layer for which a thickness is being measured may be formed on the pattern structure. The first layer may be a layer having high transparency for some wavelengths of light. For example, the first layer may be a photoresist layer.

The first light irradiation unit 104 may include a first light source. First light generated by the first light irradiation unit 104 may be incident on the substrate 200 and transmitted into the first layer on the substrate 200.

The first light may be light for obtaining a positional coordinate of a bottom surface of the first layer in a Z-axis (e.g., vertical) direction (i.e., a direction perpendicular to a major surface of the substrate, such as the bottom surface of the substrate). The first light may be incident on the first layer and transmitted into the first layer, and mostly reflected from a bottom surface of the first layer. A reflected light of the first light may be referred to as first reflected light. The first light may be visible light or infrared light. The first light may have a first wavelength within a range of about 450 nm to about 1050 nm.

The second light irradiation unit 106 may include a second light source. Second light generated by the second light source may be incident on the first layer on the substrate 200.

The second light may be light for obtaining positional coordinates of an upper surface of the first layer in the Z-axis direction. The second light may be mostly reflected from an upper surface of the first layer. The reflected light of the second light may be referred to as second reflected light. The second light may be hardly transmitted into an inner portion of the first layer such that relatively little of the second light reaches the bottom surface of the first layer. The second light may have a second wavelength shorter than the first wavelength. For example, the second light may be ultraviolet light. The second wavelength may be within a range of about 100 nm to about 400 nm.

The first sensing unit 110 may sense the first reflected light, and may generate first preliminary data from the first reflected light. In example embodiments, the first light irradiation unit 104 and the first sensing unit 110 may form an ellipsometer configured to measure the phase and amplitude of the first reflected light. In some example embodiments, the first light irradiation unit 104 and the first sensing unit 110 may each be physically separate components.

The first preliminary data may be raw data for measuring a thickness of the first layer. The first preliminary data may be generated from information such as the reflectivity Y and/or phase difference A measured from the first reflected light. In some example embodiments, the first preliminary data may be provided as a map indicating a positional coordinate of the bottom surface of the first layer in the Z-axis direction for a plurality of horizontal positions (e.g., X-Y coordinates). The first preliminary data may include noise data having irregularities.

The second sensing unit 112 may sense the second reflected light, and may generate second preliminary data from the second reflected light. In example embodiments, the second sensing unit 112 may form an ellipsometer configured to measure the phase and amplitude of the second reflected light. In some example embodiments, the second light irradiation unit 106 and the second sensing unit 112 may each be physically separate components.

The second preliminary data may be raw data for measuring the thickness of the first layer. The second preliminary data may be generated from information such as the reflectivity Ψ and/or phase difference A from the second reflected light. In some example embodiments, the second preliminary data may be provided as a map indicating a positional coordinate of the upper surface of the first layer in the Z-axis direction for each of a plurality of horizontal positions (e.g., X-Y coordinates) of the front side of the substrate 200. The second preliminary data may include noise data having irregularities.

The data processor 120 may be connected to the first and second sensing units 110 and 112. The first and second preliminary data may be processed by the data processor to obtain the first and second data, respectively. Also, the data processor may calculate a thickness of the first layer using the first and second data.

The data processor 120 may be communicatively connected to the first and second sensing units 110 and 112 via a data transmission medium including a cable transmission link and/or a wireless transmission link. The data processor 120 may receive data measured by the first and second sensing units 110 and 112 by way of the data transmission medium.

Particularly, the data processor 120 may extract valid data and noise data from the first and second preliminary data received from the first and second sensing units 110 and 112, respectively. The valid data from which the noise data is removed from the first preliminary data by the data processor 120 may serve as the first data. The valid data from which the noise data is removed from the second preliminary data by the data processor 120 may serve as the second data.

Skew data may be calculated by the processing unit 120 based on a difference between the first and second data. For example, the skew data may be the difference between the positional coordinate of the upper surface of the first layer in the Z-axis direction and the positional coordinate of the lower surface of the first layer in the Z-axis direction for each of a plurality of horizontal positions (e.g., X-Y coordinates). The skew data may be provided as a map representing the thickness of the first layer for each of the plurality of horizontal positions. Accordingly, the thickness of the first layer and a distribution of the thickness of the first layer may be obtained for the plurality of horizontal positions based on the skew data.

In example embodiments, the data processor 120 may further include a memory unit for storing data about the thickness of the first layer.

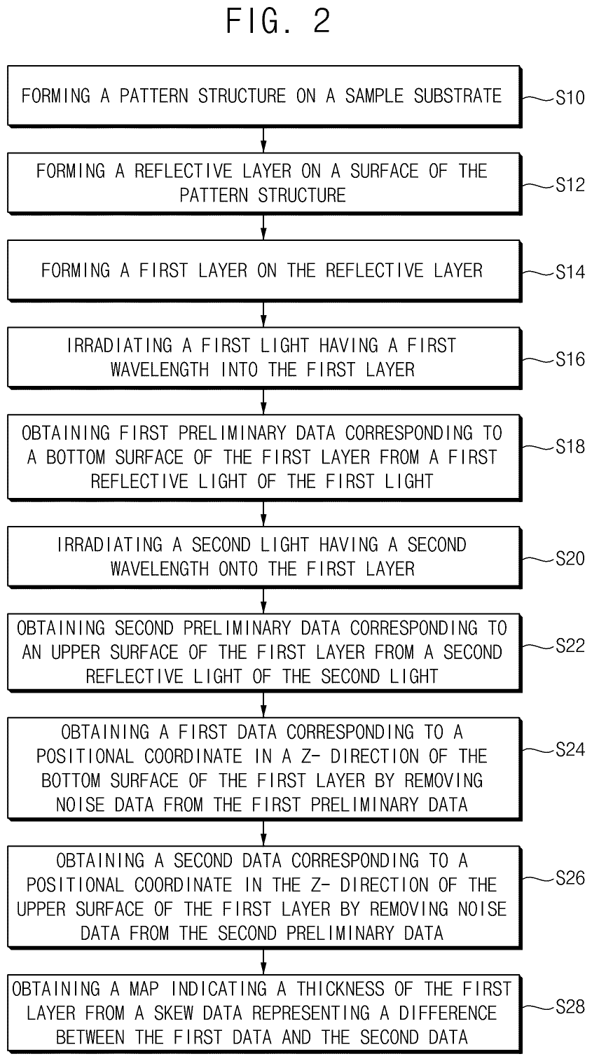

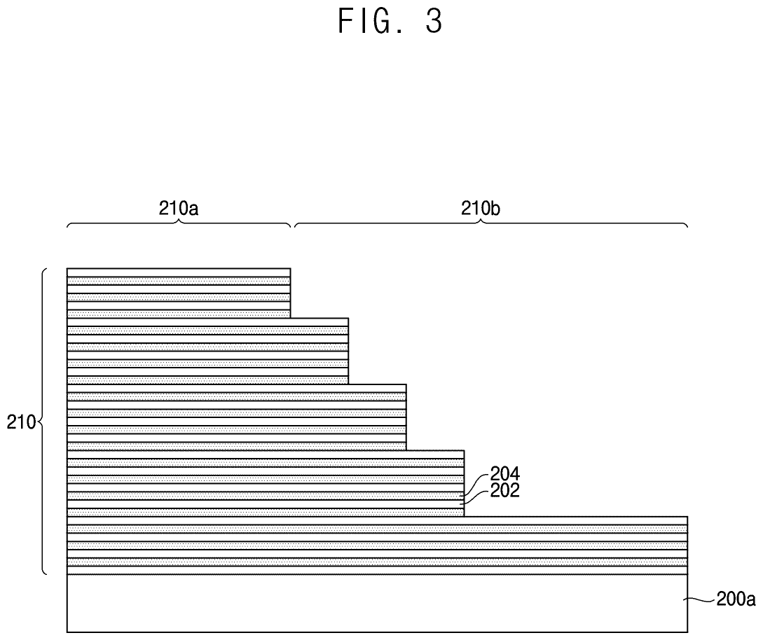

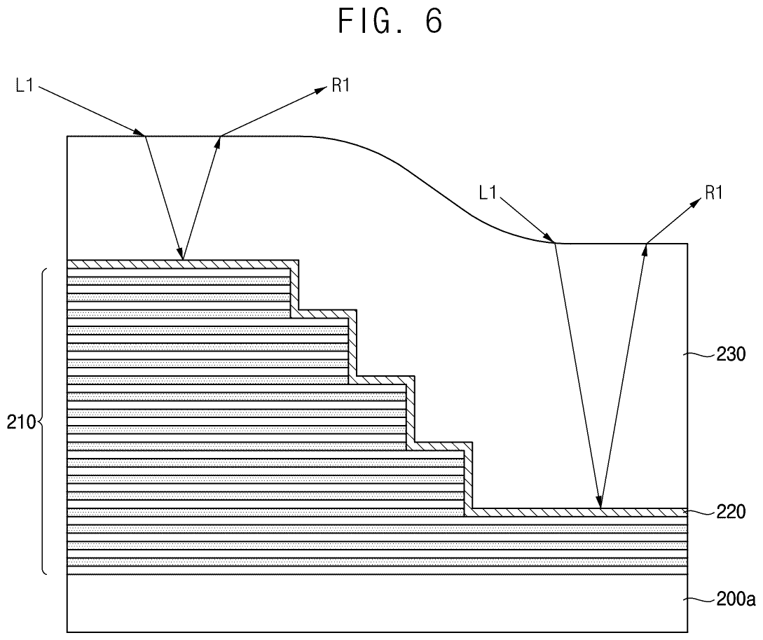

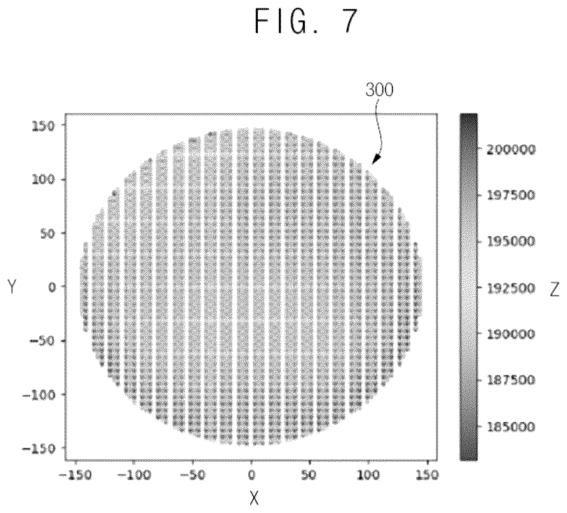

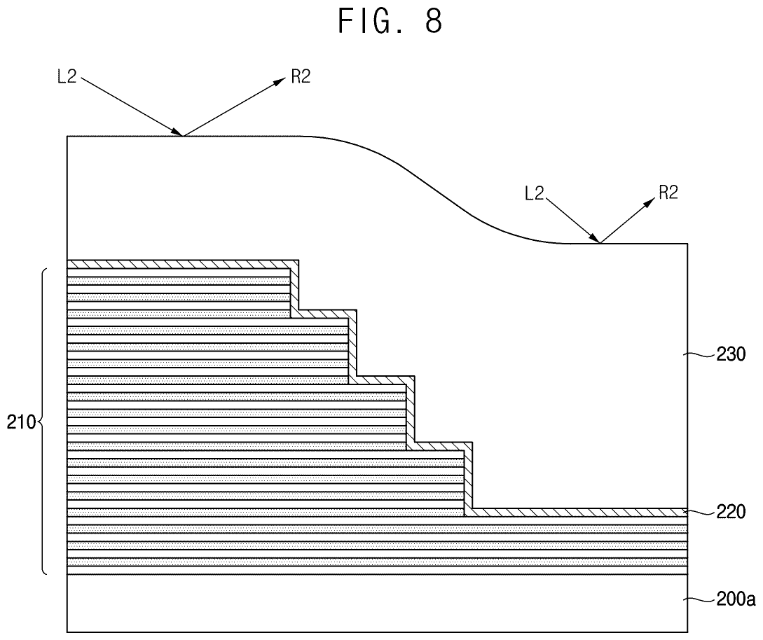

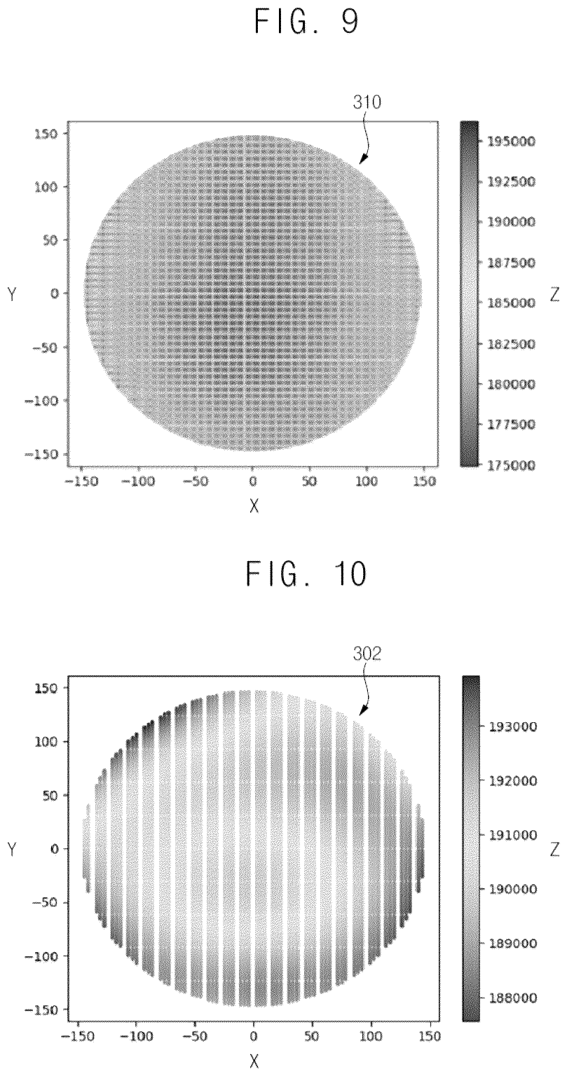

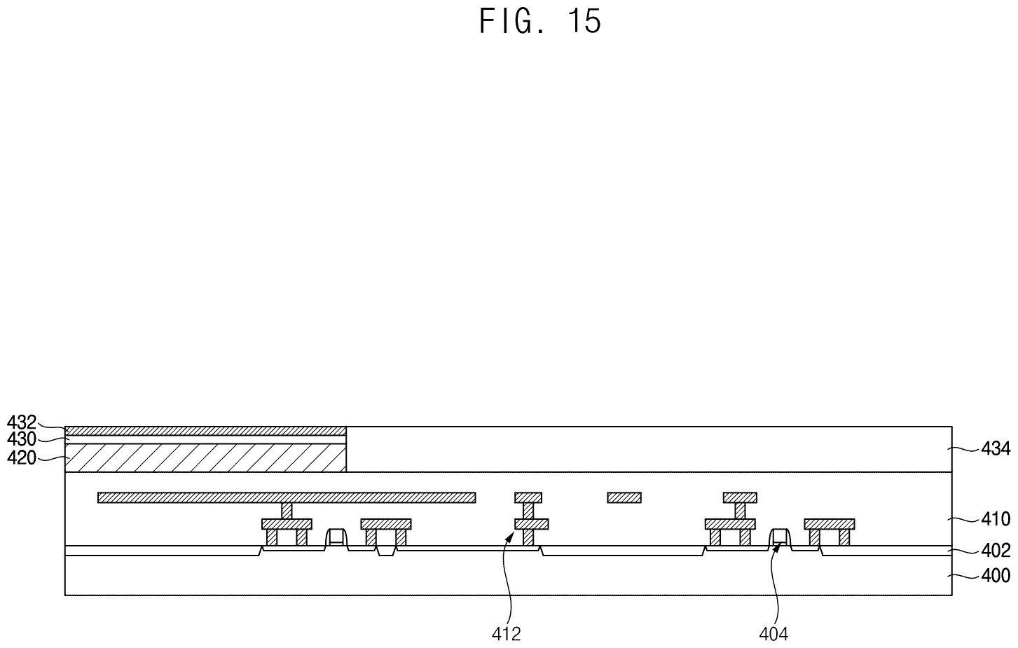

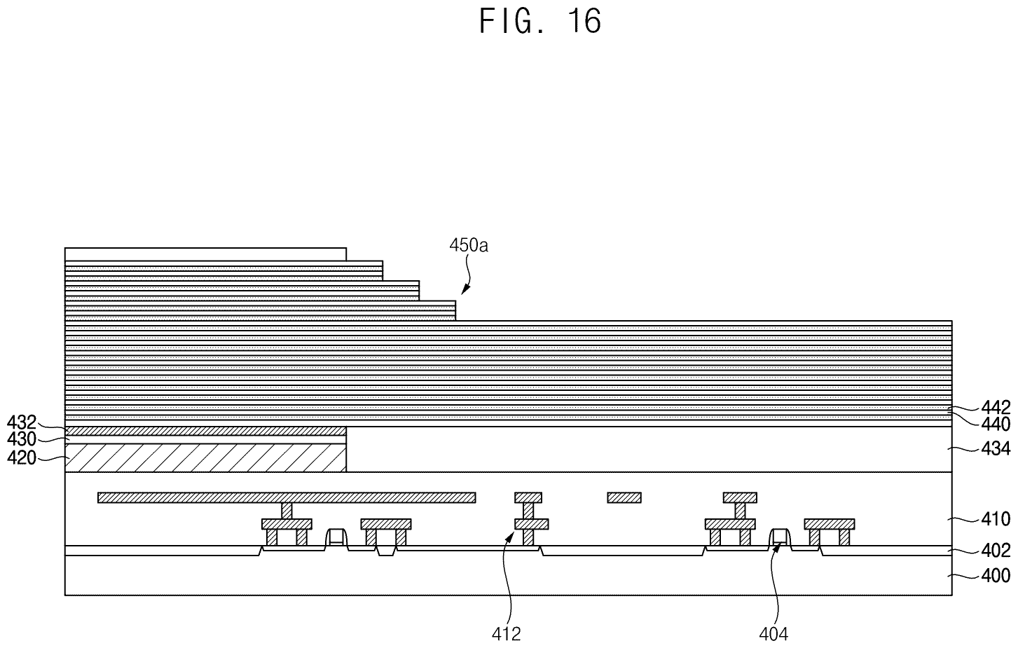

FIG. 2 is a flowchart illustrating a method for measuring a thickness of a first layer on pattern structures according to example embodiments. FIGS. 3 to 6 and 8 are cross-sectional views illustrating a method of measuring a thickness of a first layer on pattern structures according to example embodiments. FIGS. 7, 10 and 11 illustrates an example of data obtained using first light according to example embodiments. FIGS. 9, 12 and 13 illustrate an example of data obtained using second light according to example embodiments. FIG. 14 illustrates an example of data about a thickness of a first layer according to example embodiments.

Hereinafter, a method for measuring the thickness of a layer using the apparatus for measuring a thickness 100 is described.

The method for measuring the thickness of a layer described below may be suitable for measuring the thickness of a photoresist layer used in processes for manufacturing a semiconductor device. In addition, the method for measuring the thickness may be suitable for measuring the thickness of the photoresist layer covering the pattern structure when the photoresist layer has a high step difference at an upper surface. The step difference of the pattern structure may be a difference between heights of an upper surface of the pattern structure depending on horizontal positions thereof.

Referring to FIGS. 2 and 3, a pattern structure 210 may be formed on a sample substrate 200a by performing processes for manufacturing the semiconductor device. (S10) Such processes may include, for example, a deposition process, a patterning process, an etching process, and/or a cleaning process.

In example embodiments, the sample substrate 200a may be a test substrate (e.g., identical or substantially similar to a production substrate but not intended for a production device) for measuring a thickness of a photoresist layer used in processes for manufacturing the semiconductor device. The pattern structure 210 formed on the sample substrate 200a may include patterns for forming a memory device such as DRAM and VNAND or a logic device.

The pattern structure 210 may have different heights of the upper surface depending on horizontal positions thereof, and a difference between heights of the upper surface of the pattern structure 210 depending on the horizontal positions thereof may be relatively high. In other words, the upper surface of the pattern structure 210 may have a high step difference. In addition, a region where the pattern structure 210 is formed and a region where the pattern structure 210 is not formed may have a step difference that is less than the high step difference.

For example, the pattern structure 210 may include a first portion 210a and a second portion 210b connected to the first portion 210a and having a stepped shape. An upper surface of the first portion 210a of the pattern structure 210 and an upper surface of the second portion 210b of the pattern structure 210 may have different heights. The first portion 210a may have a flat upper surface, and may be positioned at a relatively high level. In addition, heights of an upper surface of the second portion 210b may decrease toward an end portion thereof or as the distance from the first portion increases. For example, the pattern structure 210 may have a structure in which a silicon oxide layer 202 and a silicon nitride layer 204 are alternately and repeatedly stacked. The pattern structure 210 may be provided as a mold structure for manufacturing a VNAND device. However, the pattern structure 210 is not limited thereto, and any pattern structure used in manufacturing the semiconductor device may be used.

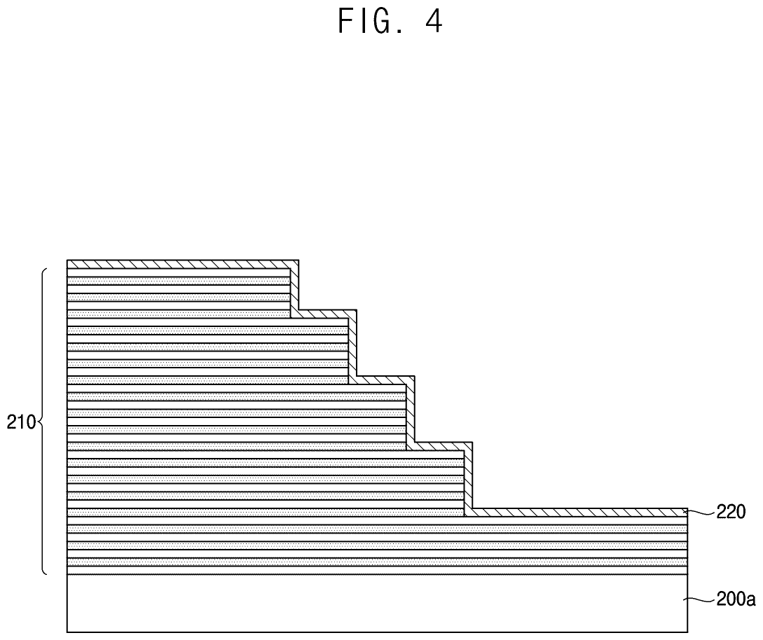

Referring to FIGS. 2 and 4, a reflective layer 220 may be conformally formed (e.g., conforming to the upper surface) on an upper surface of the pattern structure 210 (S12). The reflective layer 220 may be a layer in which the first light may be reflected without transmitting or minimal transmitting into the reflective layer, when used in subsequent processes for measuring a thickness of a layer. The reflective layer 220 may have a transparency lower than a transparency of a first layer 230 (e.g., the reflective layer 220 may have a lower transmittance for the first light than the transmittance of the first layer 230), which is a target layer for measuring the thickness. In addition, the reflective layer 220 may be formed of and/or include a material having a high step coverage characteristic in a deposition process for applying the reflective layer.

In example embodiments, the reflective layer 220 may be formed of and/or include polysilicon or a metal. The metal may be, e.g., tungsten, titanium, titanium nitride, tantalum, tantalum nitride, aluminum, or the like. A thickness of the reflective layer 220 may be sufficient to coat the pattern structure 210 and embodiments are not limited to any particular thickness. The reflective layer 220 may be formed to have a uniform thickness on the surface of the pattern structure 210. The reflective layer 220 may be formed using a deposition process.

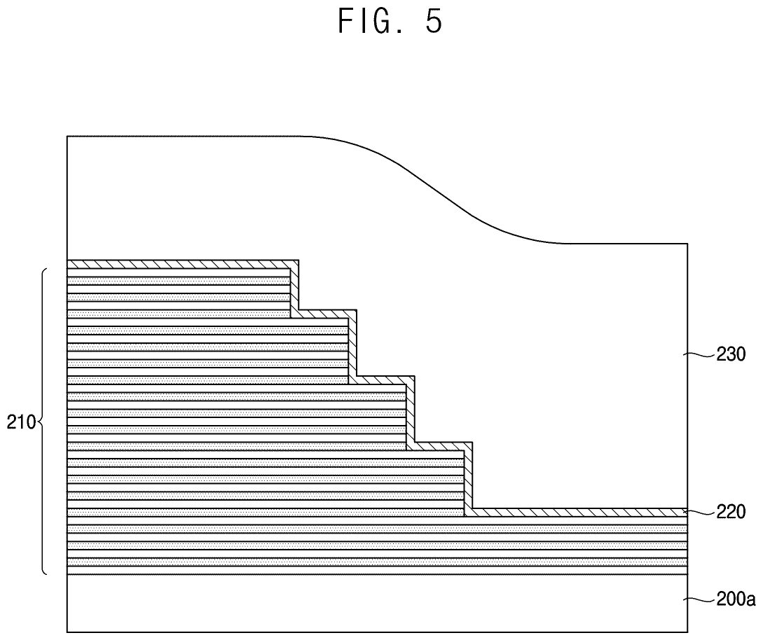

Referring to FIGS. 2 and 5, the first layer 230, which is a target layer (e.g., the layer whose thickness is being measured) for measuring the thickness, may be formed on the reflective layer 220 (S14). In example embodiments, the first layer 230 may be a photoresist layer. For example, a photoresist may be applied as a coat by a spin coating process on the reflective layer 220, and the coat of photoresist may be dried by a bake process to form the photoresist layer.

Due to the step difference of the pattern structure 210, the thickness of the first layer 230 may be different depending on the horizontal position thereof. For example, the first layer 230 on the first portion 210a of the pattern structure 210 and the first layer 230 on the second portion 210b of the pattern structure 210 may have different thicknesses. In addition, the thickness of the first layer 230 may be different depending on the horizontal position. For example, in the upper surface of the sample substrate 200a, a thickness of the first layer 230 formed on a central region may be different from a thickness of the first layer 230 formed on an edge region.

The sample substrate 200a on which the first layer 230 is formed may be loaded onto the stage 102 of the apparatus for measuring a thickness 100.

Referring to FIGS. 2, 6, and 7, first light L1 having a first wavelength may be irradiated from the first light source into the first layer 230 (S16). First reflected light R1 reflected from a bottom surface of the first layer 230 may be detected by the first sensing unit 110, and first preliminary data 300 may be extracted by the first reflected light R1. (S18)

In example embodiments, the first light L1 may be irradiated to an entire upper surface or a portion of the upper surface of the first layer 230 in a scanning manner (e.g., moving horizontally to measure the thickness at different horizontal positions). An incident angle at which the first light L1 is incident on the first layer 230 may not be limited to any particular angle, and may be a predetermined angle between 0 degrees and 90 degrees. Preferably, the incident angle may be less than 60 degrees.

The first light L1 may be refracted by the upper surface of the first layer 230, and may be incident or transmitted into an inner portion of the first layer 230. Then, the first light L1 may be reflected from an upper surface of the reflective layer 220 contacting the bottom surface of the first layer 230. The first light L1 may be provided to obtain a positional coordinate of the bottom surface of the first layer 230 in the Z-axis direction for a plurality of horizontal positions. In order to accurately extract the first preliminary data 300 using the first light L1, most of the first light L1 should be reflected from the bottom surface of the first layer 230 (i.e., the upper surface of the reflective layer 220), and the first light L1 should not be transmitted into a portion under the first layer 230.

As described above, the reflective layer 220 may contact the bottom surface of the first layer 230, so that the first light L1 should not pass through the portion under the first layer 230. The first light L1 may be mostly reflected from the bottom of the first layer 230. In example embodiments, the first light L1 may be visible light or infrared light. The first wavelength of the first light L1 may be between 450 nm to 1050 nm. However, the first wavelength of the first light may not be limited thereto, and other light sources producing lights of different wavelengths may be used. In addition, the first wavelength of the first light L1 may be changed according to a material of the first layer 230 for measuring the thickness. For example, the first wavelength may be changed to a wavelength that transmits in the material of the first layer 230 but not in the material of the reflective layer 220.

If the reflective layer 220 were not formed on the pattern structure 210 as described in S12, the first light L1 may be transmitted inside of the pattern structure 210 under the first layer 230. In this case, since the first light L1 is not reflected from the bottom surface of the first layer 230, the positional coordinate of the bottom surface of the first layer 230 in the Z-axis direction may not be accurately extracted using the first preliminary data 300 obtained by the first reflected light R1.

The first preliminary data 300 may be generated from the first reflected light R1 reflected from the upper surface of the reflective layer 220. As shown in FIG. 7, the first preliminary data 300 may be displayed as a first map indicating a positional coordinate of the bottom surface of the first layer 230 in the Z-axis direction for a plurality of horizontal positions. For example, the first sensing unit 110 may generate the first preliminary data 300 using reflectivity Ψ and/or phase difference Δ from the first reflected light R1. The first preliminary data 300 may include noise data having irregularities.

Referring to FIGS. 2, 8, and 9, second light L2 having a second wavelength may be irradiated from the second light source onto the first layer 230. (S20) The second light L2 is reflected from the upper surface of the first layer 230 resulting in the second reflected light R2. The second reflected light R2 may be detected by the second sensing unit 112, and second preliminary data be extracted by the second reflected light R2. (S22)

In example embodiments, the second light L2 may be irradiated to the entire upper surface or a portion of the upper surface of the first layer 230 in a scanning manner (e.g., moving horizontally to measure at different horizontal locations). An incident angle at which the second light L2 is incident on the first layer 230 may not be limited to any particular value, and may be a predetermined angle between 0 degrees and 90 degrees. Preferably, the incident angle may be less than 60 degrees.

The second light L2 may be provided to obtain a positional coordinate of the upper surface of the first layer 230 in the Z-axis direction for a plurality of horizontal positions. In order to accurately extract the second preliminary data through the second light L2, most of the second light L2 should be reflected from the upper surface of the first layer 230, and the second light L2 should not be transmitted into a portion under the upper surface of the first layer 230. The second light L2 may have a wavelength having low transmittance through the first layer 230.

The second wavelength may be shorter than the first wavelength. In example embodiments, the second light L2 may be ultraviolet light. The second wavelength may be between about 100 nm to about 400 nm. However, the second wavelength may not be limited thereto, and other light sources producing other wavelengths of light may be used. In addition, the second wavelength of the second light L2 may be changed according to the material of the first layer 230 for measuring the thickness. For example, the second wavelength may be changed to a wavelength that does not transmit through the first layer 230.

The second preliminary data 310 may be generated from the second reflected light R2 reflected from the upper surface of the first layer 230. As shown in FIG. 9, the second preliminary data 310 may be displayed as a map indicating a positional coordinate of the upper surface of the first layer 230 in the Z-axis direction for a plurality of horizontal positions. For example, the second sensing unit 112 may generate the second preliminary data 310 using reflectivity Ψ and/or phase difference A from the second reflected light R2. The second preliminary data 310 may include noise data having irregularities.

Referring to FIGS. 2, 10 and 11, first data 302 and first noise data 304 may be extracted from the first preliminary data 300 through the data processor 120. (S24)

The first data 302 may be obtained by removing noise from the first preliminary data 300 and extracting only desired valid data. The process of extracting the first data 302 may use a noise reduction technique, e.g., a Zernike polynomial fitting model.

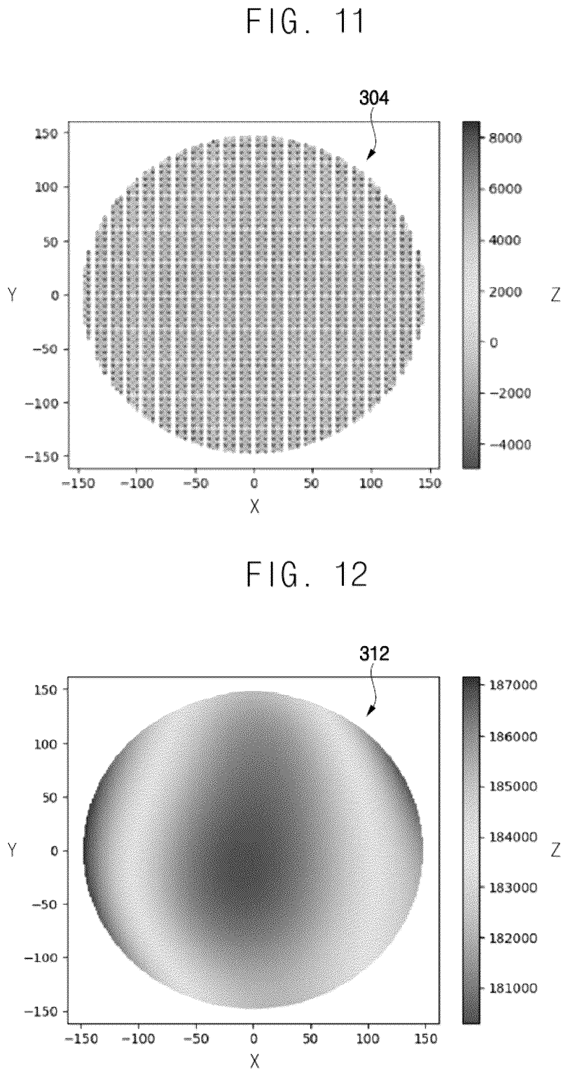

As shown in FIG. 10, the first data 302 may be displayed as a map indicating a positional coordinate of the bottom surface of the first layer 230 in the Z-axis direction for a plurality of horizontal positions. That is, the first data 302 may represent a height of the bottom surface of the first layer 230. As shown in FIG. 11, the first noise data 304 may also be displayed as a map indicating a positional coordinate of the bottom surface of the first layer 230 in the Z-axis direction for a plurality of horizontal positions.

Referring to FIGS. 2, 12, and 13, second data 312 and second noise data 314 may be extracted from the second preliminary data 310 through the data processor 120. (S26)

The second data 312 may be obtained by removing noise from the second preliminary data 310 and extracting only desired valid data. The process of extracting the second data 312 may use a noise reduction technique, e.g., a Zernike polynomial fitting model.

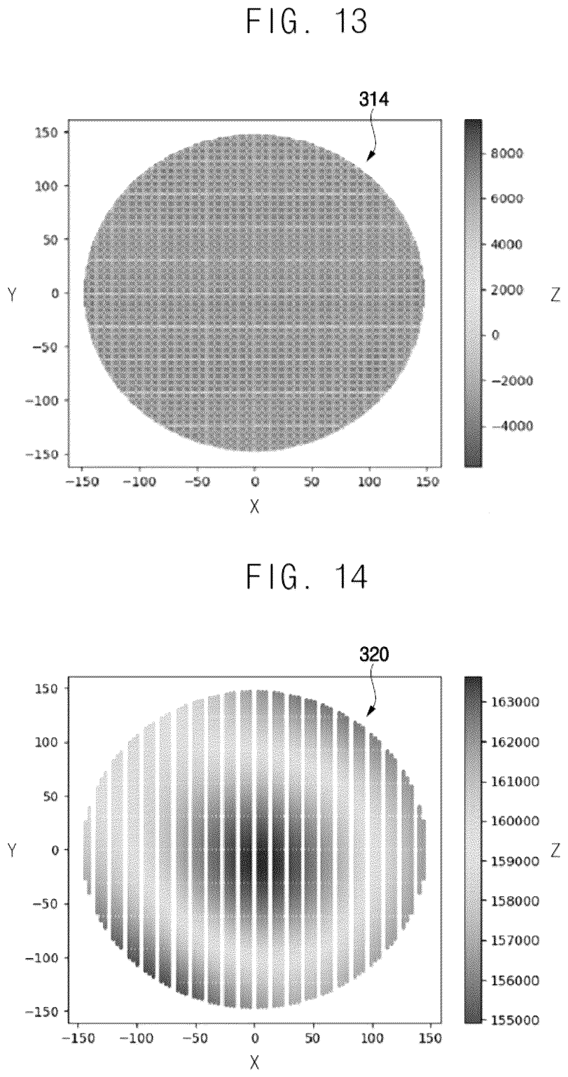

As shown in FIG. 12, the second data 312 may be displayed as a map indicating a positional coordinate of the upper surface of the first layer 230 in the Z-axis direction for a plurality of horizontal positions. That is, the second data 312 may represent a height of the upper surface of the first layer 230. As shown in FIG. 13, the second noise data 314 may also be displayed as a map indicating a positional coordinate of the upper surface of the first layer 230 in the Z-axis direction for a plurality of horizontal positions.

Referring to FIGS. 2 and 14, a skew data 320 representing a difference between the first data 302 and the second data 312 may be calculated. (S28) When a reference coordinate of the first data 302 and a reference coordinate of the second data 312 are different from each other, a correction of the coordinate may be performed. The skew data 320 may be displayed as a map indicating a thickness of the first layer 230 at a plurality of horizontal position. The thickness and a distribution of the thickness of the first layer 230 may be obtained for each of the plurality of horizontal positions by the skew data 320. Data for each horizontal position on the front surface of the substrate may be commonly referred to as in-wafer global data.

Therefore, the position in the Z-direction of the bottom surface of the first layer 230 may be accurately detected using the first light L1 having the first wavelength reflected from the bottom surface of the first layer 230. The position in the Z-direction of the upper surface of the first layer 230 may be accurately detected using the second light L1 having the second wavelength reflected from the upper surface of the first layer 230. In addition, the thickness of the first layer 230 may be accurately calculated using the positions in the Z-direction of the bottom and upper surfaces of the first layer 230. Particularly, the thickness of the first layer 230 formed on the pattern structure 210 having a step difference may be accurately calculated at each horizontal position on the front surface of the substrate.

Hereinafter, a method for manufacturing a semiconductor device using embodiments of the method for measuring a thickness is described.

FIGS. 15 to 27 are cross-sectional views illustrating a method for manufacturing a semiconductor device according to example embodiments.

Referring to FIG. 15, an isolation layer 402 may be formed on a substrate 400, and lower transistors 404 may be formed on the substrate 400 and the isolation layer 402. The lower transistors 404 may each include a gate structure and impurity regions.

The substrate 400 may be a semiconductor substrate for manufacturing an actual semiconductor device. The same processes may be performed on a plurality of substrates in a semiconductor fabrication line to form the semiconductor devices and the substrate 400 may be identical to the other substrates of the plurality of substrates.

A first lower insulating interlayer 410 may be formed to cover the lower transistors 404. Lower wirings 412 may be formed in the first lower insulating interlayer 410.

A common plate pattern 420 may be formed on the first lower insulating interlayer 410. The common plate pattern 420 may include, e.g., a polysilicon layer or a single crystal silicon layer. The common plate pattern 420 may serve as a common source region.

A lower sacrificial layer structure 430 and a support layer pattern 432 may be formed on the common plate pattern 420. The lower sacrificial layer structure 430 may include first to third lower sacrificial layers sequentially stacked. In this case, the first and third lower sacrificial layers may be formed of and/or include, e.g., an oxide such as silicon oxide, and the second lower sacrificial layer may be formed of and/or include, e.g., a nitride such as silicon nitride. The support layer pattern 432 may be formed of and/or include a material having an etch selectivity with respect to the first to third lower sacrificial layers, e.g., polysilicon undoped with impurities or polysilicon doped with n-type impurities.

A second lower insulating interlayer 434 may be formed on both sides of or around a structure which may be defined by a stack of the common plate pattern 420, the lower sacrificial layer structure 430 and the support layer pattern 432. An upper surface of the common plate pattern 420 and an upper surface of the second lower insulating interlayer 434 may be coplanar with each other, and may be substantially flat. In some example embodiments, an upper surface of the support layer pattern 432 may be coplanar with the upper surface of the second lower insulating layer 434.

Referring to FIG. 16, a first insulation layer 440 and a first sacrificial layer 442 may be alternately and repeatedly stacked on the support layer pattern 432 and the second lower insulating interlayer 434. For example, the first insulation layer 440 may be deposited on the support layer pattern 432 and the second lower insulating layer 434 through a deposition process and then the first sacrificial layer 442 may be deposited on the first insulation layer 440 through another deposition process. This pattern may continue to alternately and repeatedly stack the first insulation layer 440 and the first sacrificial layer 442. The first insulation layer 440 may include silicon oxide. The first sacrificial layer 442 may include a material having an etch selectivity with respect to the first insulation layer 440, e.g., a nitride such as silicon nitride.

Thereafter, several upper layers of the first insulation layers 440 and the first sacrificial layers 442 may be sequentially etched to form a first mold structure 450a including a first stepped portion at an upper edge portion thereof. For example, a mask may be applied to portions of the substrate and portions of at least one layer of the first insulation layers 440 and the first sacrificial layers 442 may be removed by an etch. This process may be repeated to sequentially etch the several upper layers of the first insulation layers 440 and the first sacrificial layers 442 to form the first mold structure 450a. The first mold structure 450a may include a first portion having an uppermost flat surface, the first stepped portion, and a second portion having a flat surface below the first step portion.

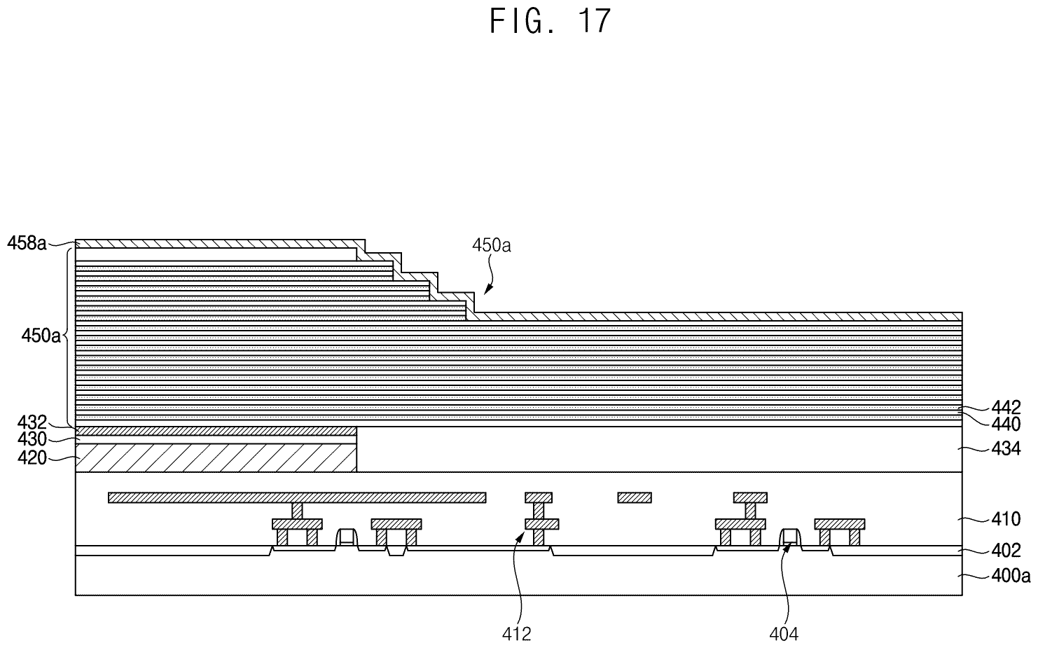

Referring to FIG. 17, one of the substrates on which the above processes have been performed may be selected as a first sample substrate 400a for measuring a thickness of a first photoresist layer.

A first reflective layer 458a may be conformally formed on the surface of the first mold structure 450a on the first sample substrate 400a. The first reflective layer 458a may be formed of a layer which reflects light having a certain wavelength without transmitting the light, in subsequent processes for measuring the thickness. The first reflective layer 458a may be formed of and/or include a material capable of reflecting light having a wavelength of about 600 nm to about 1050 nm. In example embodiments, the first reflective layer 458a may include polysilicon or a metal. The metal may include tungsten, titanium, titanium nitride, tantalum, tantalum nitride, aluminum, or the like. A thickness of the first reflective layer 458a may not be limited to any particular value so long as it is sufficient to block (e.g., not transmit) the light. The first reflective layer 458a may be formed to a uniform thickness on the surface of the first mold structure 450a.

Since the first reflective layer 458a is formed to measure the thickness of the first photoresist layer 460, the first reflective layer 458a may be formed only on the first sample substrate 400a and other substrates of the plurality of substrates may not include the reflective layer. Therefore, the first reflective layer 458a may not be formed on a substrate (i.e., a substrate not selected as the first sample substrate) for manufacturing an actual semiconductor device.

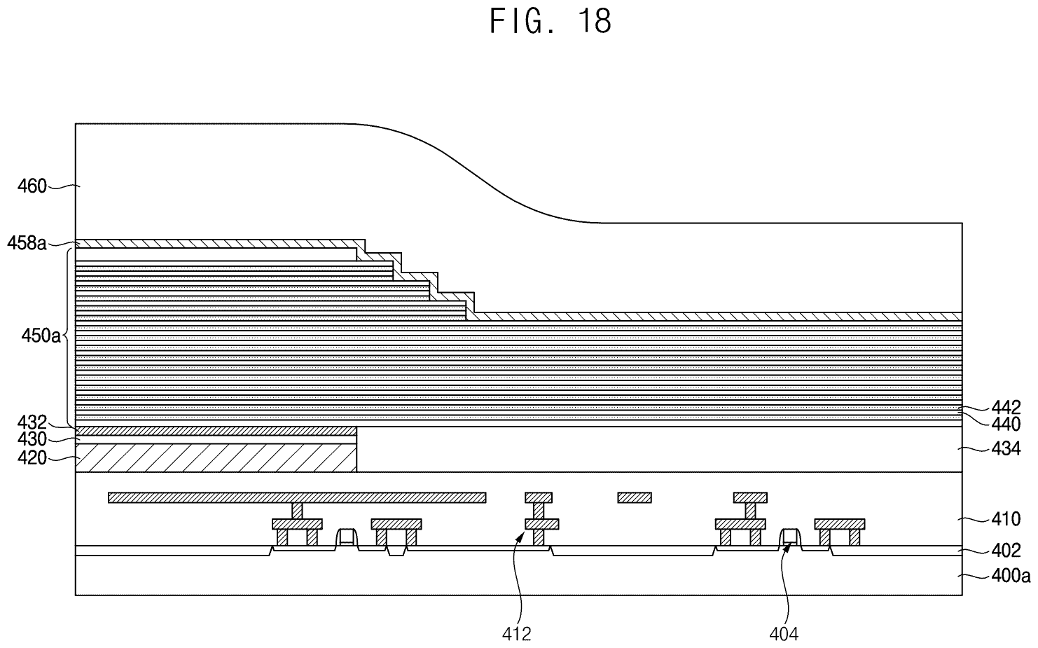

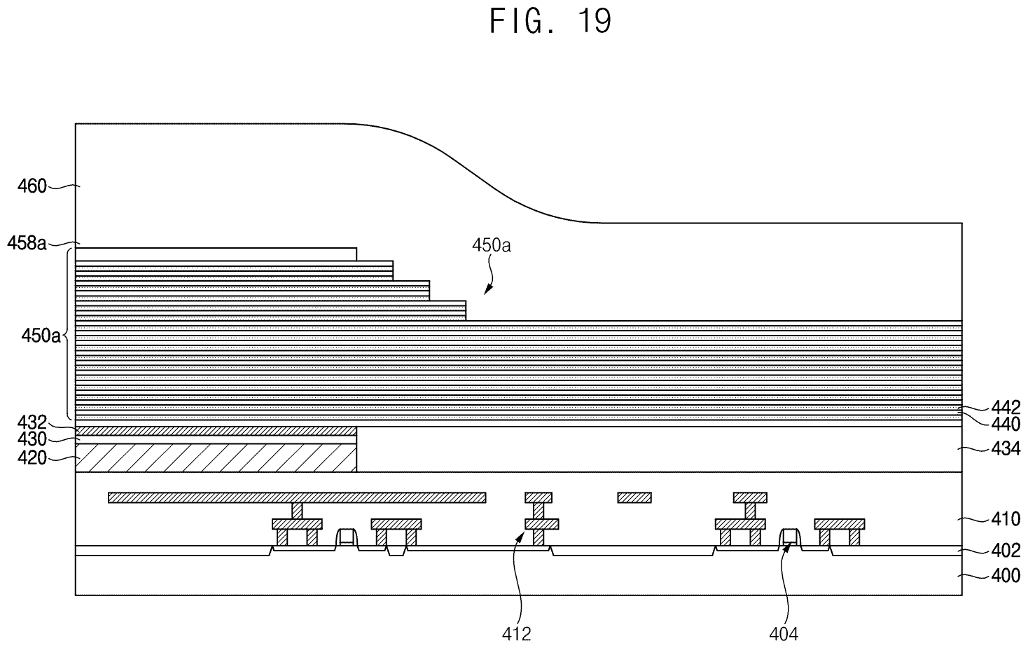

Referring to FIG. 18, the first photoresist layer 460 may be formed on the first reflective layer 458a to cover the first reflective layer 458a. A spin coating process may result in first photoresist material being spin coated onto the first reflective layer 458a, and the first photoresist material may be dried by a bake process to form the first photoresist layer 460.

The first reflective layer 458a may be disposed directly below the first photoresist layer 460 (i.e., a target layer for measuring the thickness). An upper surface of the first reflective layer 458a and a bottom surface of the first photoresist layer 460 may contact each other and may be coincident. Planar portions of the upper surface of the first reflective layer 458a and the bottom surface of the first photoresist layer 460 may be substantially coplanar with each other.

With the first photoresist layer 460 in place, the thickness of the first photoresist layer 460 formed on the first sample substrate 400a may be measured. Processes for measuring the thickness of the first photoresist layer 460 may be substantially the same as those described with reference to FIGS. 2 to 14.

Accordingly, a map representing the thickness of the first photoresist layer 460 may be calculated for a plurality of horizontal positions. The thickness of the first photoresist layer 460 and a distribution of the thickness of the first photoresist layer 460 may be obtained for a plurality of horizontal position.

It may be determined, based on the map representing the thickness of the first photoresist layer 460, whether each of the thickness of the first photoresist layer 460 and the distribution of the thickness of the first photoresist layer 460 satisfy a target allowable range. In addition, process conditions for forming the first photoresist layer 460 may be extracted so that each of the thickness and the distribution of the thickness of the first photoresist layer 460 may satisfy the target allowable range. The process conditions may then be applied to the process for manufacturing the actual semiconductor device, where the first photoresist layer 460 may be formed directly on the surface of the first mold structure 450a without an intervening reflective layer.

In order to determine the process conditions in which each of the thickness of the first photoresist layer 460 and the distribution of the thickness may satisfy the target allowable range, the first photoresist layer 460 may be repeatedly formed while changing process conditions such as coating conditions and baking conditions, or the like. In some embodiments, the first photoresist layer 460 may be removed from the sample substrate 400a after measuring the thickness of the first photoresist layer 460 and the distribution of the thickness of the first photoresist layer 460 and prior to formed a new photoresist layer with changed process conditions. In other embodiments, a second sample substrate may be used to apply a first photoresist layer 460. In this manner, each of the thickness of the first photoresist layer 460 and the distribution of the thickness of the first photoresist layer 460 may be repeatedly obtained using different process conditions. The coating conditions may include, e.g., rotation RPM during coating and the duration of the coating process, and the baking conditions may include, e.g., baking temperature and the duration of the baking process.

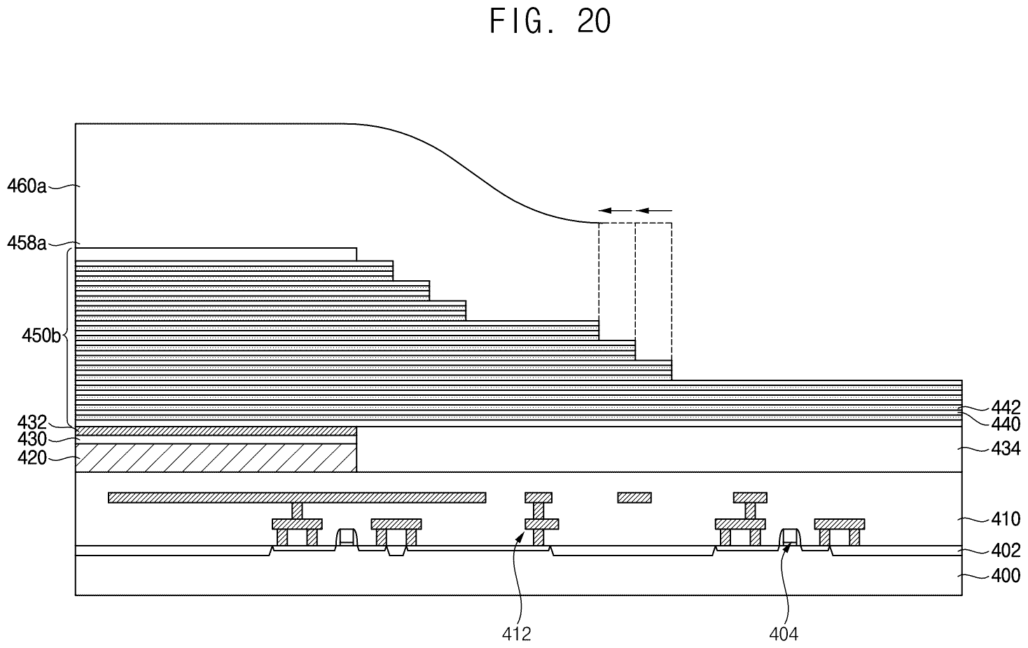

Referring to FIG. 19, the first photoresist layer 460 may be formed on the substrate 400 on which the first reflective layer 458a is not formed to continue the manufacturing process of the semiconductor device using the process conditions determined from the sample substrate 400a.

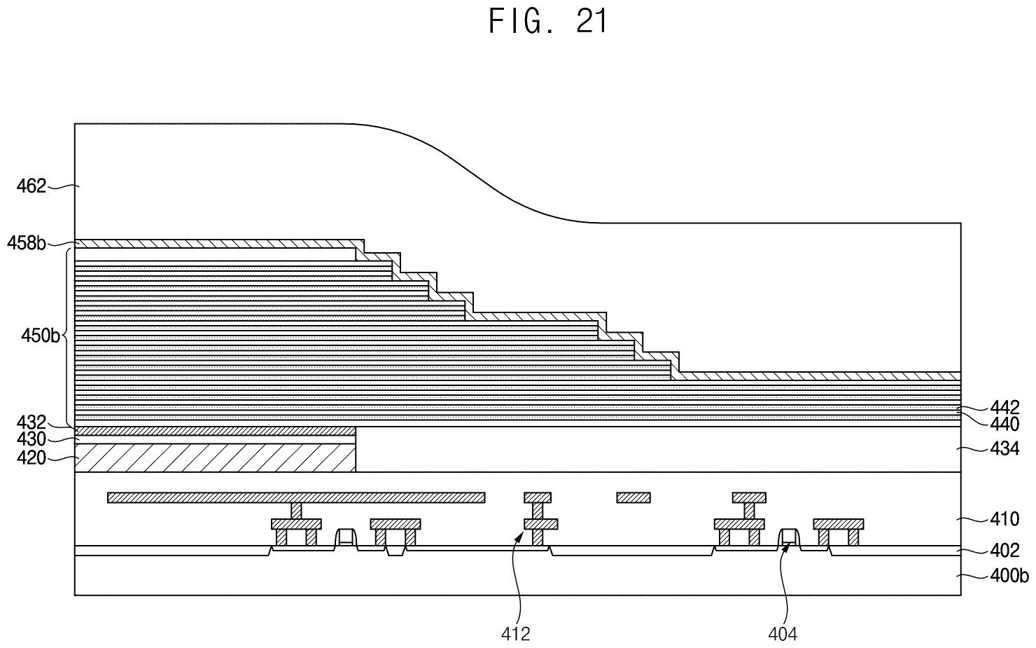

Referring to FIG. 20, an exposure process and a development process may be performed on the first photoresist layer 460 to form a first photoresist pattern 460a. One or a plurality of first insulation layers 440 and first sacrificial layers 442 included in the first mold structure 450a may be subsequently etched using the first photoresist pattern 460a as an etching mask.

In addition, an edge portion of the first photoresist pattern 460a may be partially removed by a trimming process, so that an area of the first photoresist pattern 460a may be decreased. Thereafter, one or a plurality of the first insulation layers 440 and the first sacrificial layers 442 included in an exposed first mold structure 450a may be further etched using the trimmed first photoresist pattern as an etch mask.

Subsequently, the trimming process for trimming the first photoresist pattern 460a and the etching process for etching an upper portion of the first mold structure 450a may be repeatedly performed to form a second mold structure 450b including a second step portion under the first step portion.

As described above, as a distribution (e.g., area) of the thickness of the first photoresist layer 460 decreases, the second mold structure 450b formed using the first photoresist pattern 460a results in a target structure (e.g., a structure designed for the device).

After the target structure is formed, a remaining first photoresist pattern 460a may be removed.

Referring to FIG. 21, one of the substrates on which the above processes have been performed may be selected as a second sample substrate 400b for measuring a thickness of a second photoresist layer.

A second reflective layer 458b may be conformally formed on a surface of the second mold structure 450b on the second sample substrate 400b. The second photoresist layer 462 may be formed on the second reflective layer 458b to cover the second reflective layer 458b.

The thickness of the second photoresist layer 462 formed on the second sample substrate 400b may be measured using the previously described techniques. Processes for measuring the thickness of the second photoresist layer 462 may be substantially the same as those described with reference to FIGS. 2 to 14.

A map representing the thickness of the second photoresist layer 462 may be calculated for a plurality of horizontal positions. Accordingly, the thickness of the second photoresist layer 462 and a distribution of the thickness of the second photoresist layer 462 may be obtained for the plurality of horizontal positions. Thereafter, process conditions for forming the second photoresist layer 462 may be extracted so that each of the thickness and the distribution of the thickness of the second photoresist layer 462 may satisfy the target allowable range through the same processes as described with reference to FIG. 18. In addition, the process conditions may be applied to the process for manufacturing the actual semiconductor device.

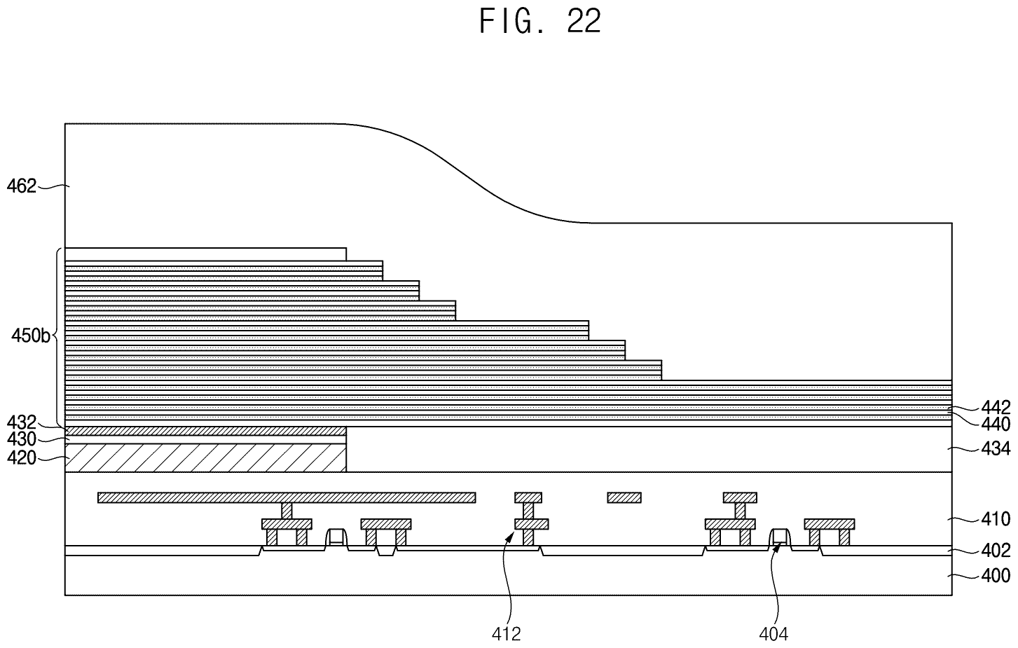

Referring to FIG. 22, the second photoresist layer 462 may be formed on the substrate 400 (i.e., a non-selected substrate as the second sample substrate) on which the second reflective layer is not formed to continue the manufacturing process of the semiconductor device using the process conditions determined from forming the second sample substrate 400b.

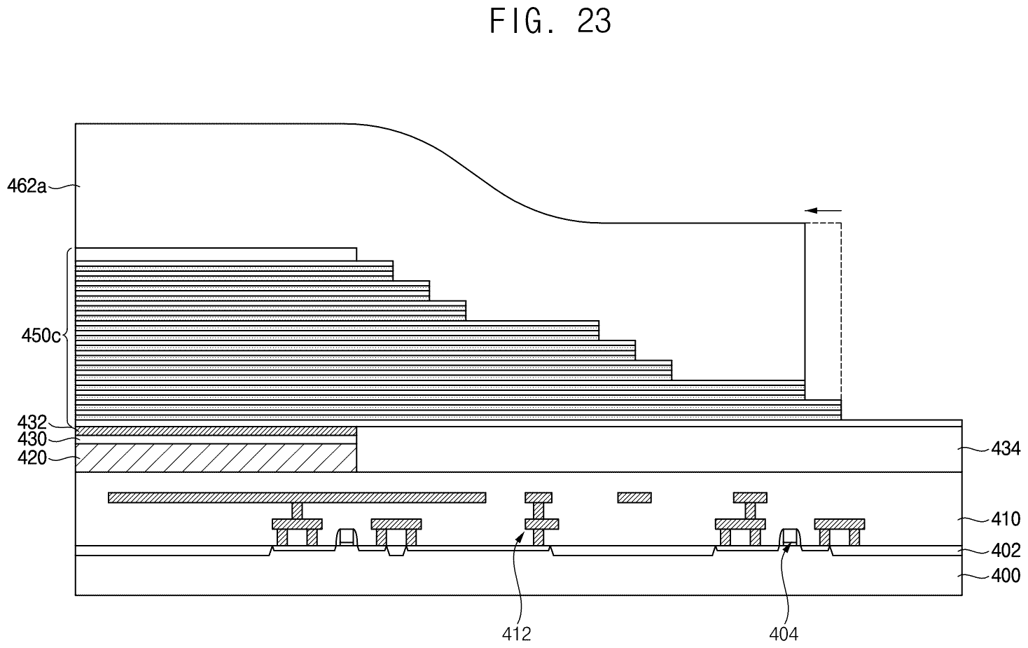

Referring to FIG. 23, an exposure process and a development process may be performed on the second photoresist layer 462 to form a second photoresist pattern 462a. One or a plurality of first insulation layers 440 and first sacrificial layers 442 included in the second mold structure 450b may be etched using the second photoresist pattern 462a as an etching mask.

Subsequently, a trimming process for trimming the second photoresist pattern 462a and an etching process for etching an upper portion of the second mold structure 450b may be repeatedly performed to form a third mold structure 450c including a third step portion under the second step portion.

By repeatedly performing the above-described processes, a mold structure including a stepped portion at an edge portion thereof may be formed. The number of steps of the mold structure may not be limited to any particular number of steps.

As the number of stacked memory cells increases, the number of the steps of the mold structure may increase. Also, the number of photo processes and etching processes for forming the mold structure including the stepped portion may be increased. Therefore, in the process for forming the mold structure, it is difficult to coat the photoresist layer having a low distribution of the thickness in the entire surface of the substrate. However, when the above-described processes are performed, the distribution of the thickness of the photoresist layer on the entire surface of the substrate may be decreased. Thus, the mold structure having a target structure may be formed.

After this, a semiconductor device may be manufactured by performing general processes for manufacturing the semiconductor device. Hereinafter, some of the subsequent processes are briefly described.

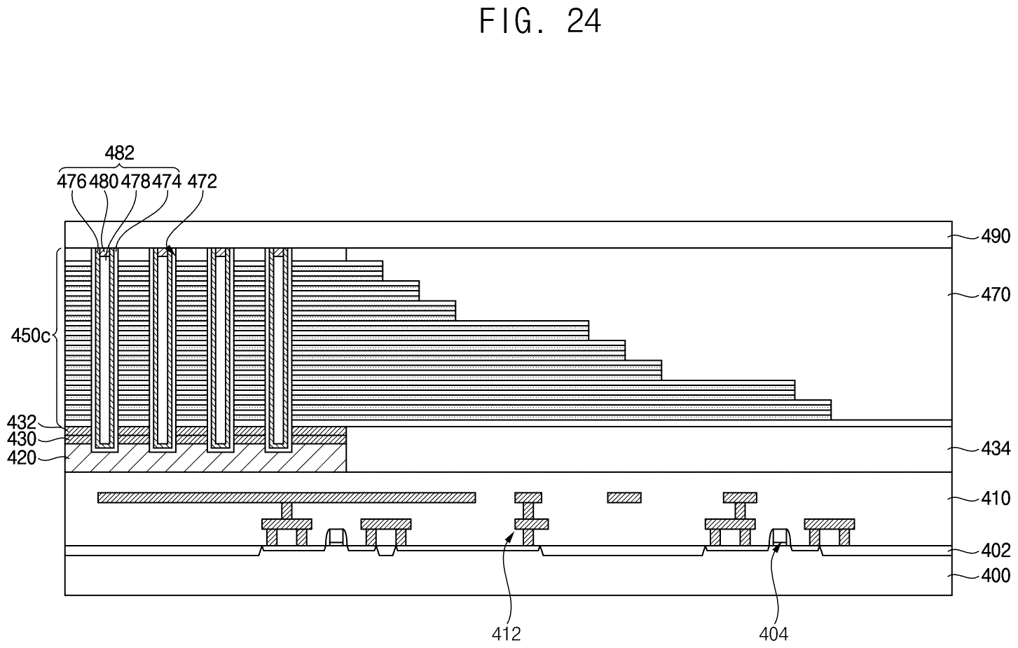

Referring to FIG. 24, a first insulating interlayer 470 may be formed on the third mold structure 450c and the second lower insulating interlayer 434.

Thereafter, the first insulating interlayer 470 may be planarized until an upper surface of the third mold structure 450c may be exposed. Thus, the first insulating interlayer 470 may cover the step portion of the third mold structure 450c.

Channel holes 472 extending from a flat upper surface of the third mold structure 450c to an upper surface of the common plate pattern 420 may be formed through the third mold structure 450c.

A preliminary channel structure 482 may be formed in the channel holes 472. In example embodiments, the preliminary channel structure 482 may include a preliminary charge storage structure 474, a channel 476, a buried insulation pattern 478 and a capping pattern 480. The preliminary charge storage structure 474 may include a preliminary first blocking layer, a preliminary charge storage layer and a preliminary tunnel insulation layer sequentially stacked on a sidewall of the channel hole 472.

A second insulating interlayer 490 may be formed on the third mold structure 450c and the preliminary channel structure 482.

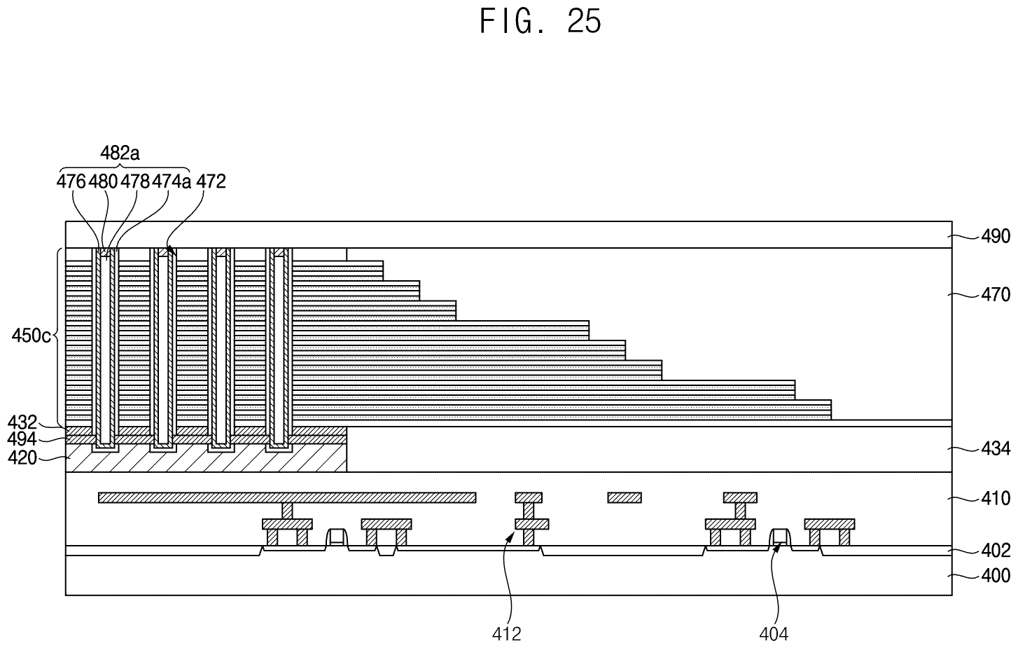

Referring to FIG. 25, an etching mask may be formed on the second insulating interlayer 490. The first and second insulating interlayers 470 and 490, the third mold structure 450c, the support layer pattern 432, lower sacrificial layer structure 430 and the second lower insulating interlayer 434 may be etched to form a first opening extending in a first direction. By performing the process, the third mold structure 450c may be cut to have a line shape.

Thereafter, a spacer may be formed on a sidewall of the first opening positioned higher than the support layer pattern 432. The lower sacrificial layer structure 430 may be selectively removed to form a first gap. The preliminary charge storage structure 474 exposed by the first gap may be selectively etched to form a charge storage structure 474a. Accordingly, a channel structure 482a may be formed in the channel hole 472.

The upper surface of the common plate pattern 420 may be exposed by the first gap. A channel connection pattern 494 may be formed to fill the first gap.

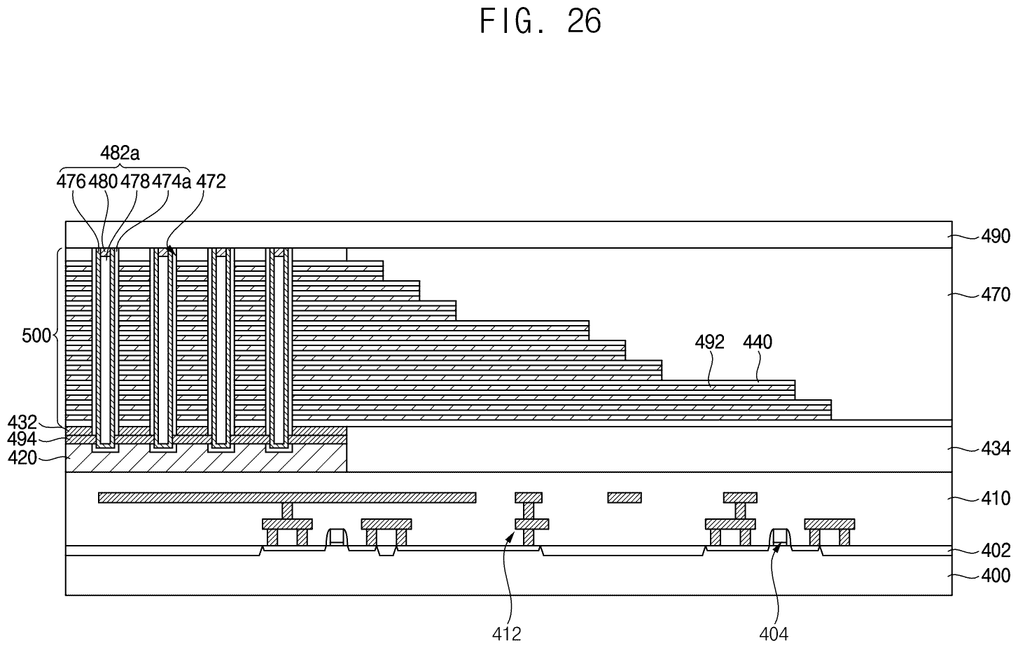

Referring to FIG. 26, the first sacrificial layers 442 exposed by the sidewall of the first opening may be removed to form second gaps. A first barrier metal layer may be formed on an inner surface of each of the second gaps, and a gate pattern 492 may be formed on the first barrier metal layer to fill each of the second gaps.

Accordingly, a cell stack structure 500 in which the first insulation layer 440 and the gate pattern 492 may be alternately and repeatedly stacked, may be formed. The cell stack structure 500 may extend in the first direction, and may have a stepped shape at an edge portion thereof.

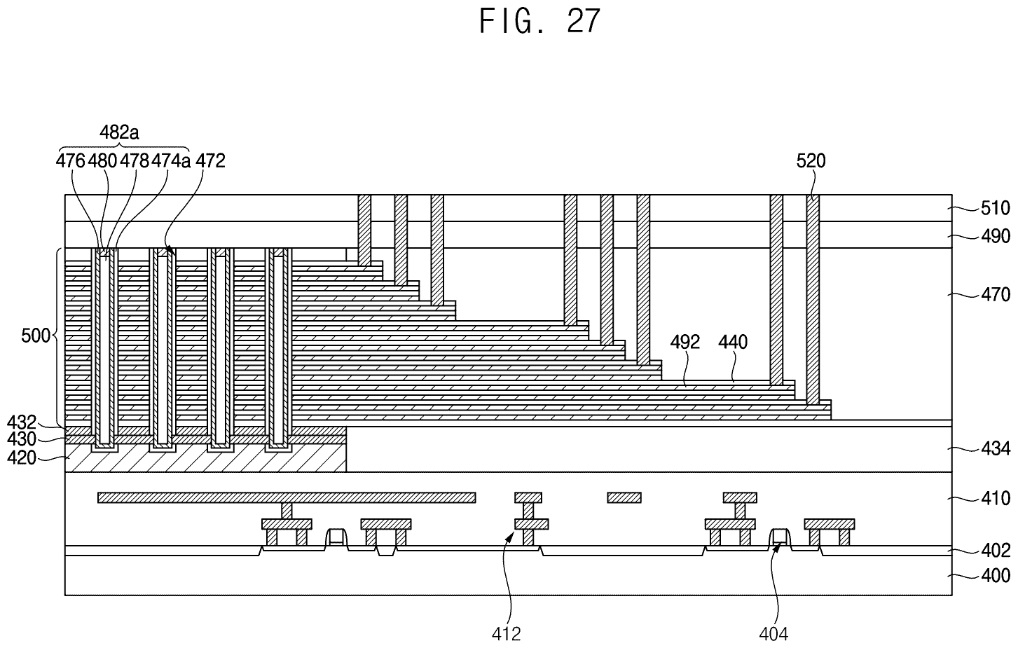

Referring to FIG. 27, a third insulating interlayer 510 may be formed to cover the second insulating interlayer 490, the cell stack structure 500 and the channel structure.

Cell contact plugs 520 may be formed through the first to third insulating interlayers 470, 490 and 510 to be electrically connected to steps of the cell stack structure 500.

Thereafter, a fourth insulating interlayer may be formed on the third insulating interlayer 510. A bit line contact may be formed through the fourth insulating interlayer and the third and second insulating interlayers 510 and 490. The bit line contact may contact the capping pattern 480 of the channel structure 482a. A bit line may be formed on the fourth interlayer.

As described above, the thickness and the distribution of the thickness of the photoresist layer may be measured for a plurality of horizontal positions. In addition, a target semiconductor device may be manufactured on the substrate by controlling conditions of manufacturing processes using the thickness and the distribution of the thickness of the photoresist layer.

The method for measuring the thickness and the distribution of the thickness may not be limited in measuring only the thickness and the distribution of the thickness of the photoresist layer used in specific processes. The method for measuring the thickness and the distribution of the thickness may be used in measuring the thickness and the distribution of the thickness of all photoresist layers or layers having high transparency used in processes for manufacturing the semiconductor device.

The method for measuring the thickness and the distribution of the thickness of the photoresist layer may be used to monitor the process for forming the photoresist layer. In addition, the method for measuring the thickness and the distribution of the thickness of the photoresist layer may be used for optimizing of process conditions for forming the photoresist layer.

Although exemplary embodiments of the present disclosure have been described above, it will be understood by those of ordinary skill in the art that various changes and modifications can be made to the present disclosure without departing from the idea and scope of the present disclosure as set forth in the appended claims.

What is claimed is:

1. A method of manufacturing a device, comprising:
forming a first layer on a first substrate, the first layer for measuring a thickness thereof;
irradiating the first layer with first light having a first wavelength that passes into the first layer;
sensing first reflected light reflected from a bottom surface of the first layer;
irradiating the first layer with second light having a second wavelength shorter than the first wavelength that reflects from the first layer;
sensing second reflected light reflected from an upper surface of the first layer;
obtaining first data corresponding to a first positional coordinate in a vertical direction of the bottom surface of the first layer from the first reflected light;
obtaining second data corresponding to a second positional coordinate in the vertical direction of the upper surface of the first layer from the second reflected light;
obtaining skew data representing a thickness of the first layer using the first and second data; and
forming one or more semiconductor devices with a second substrate including forming at least one layer on the second substrate using process conditions determined from the skew data.

2. The method of claim 1, wherein obtaining the first data comprises:
obtaining first preliminary data that is raw data corresponding to the first positional coordinate in the vertical direction of the bottom surface of the first layer from the first reflected light; and,
removing noise data from the first preliminary data to obtain the first data.

3. The method of claim 2, wherein obtaining the first data from the first preliminary data uses a Zernike polynomial fitting model.

4. The method of claim 1, wherein obtaining the second data comprises:
obtaining second preliminary data corresponding to the second positional coordinate in the vertical direction of the upper surface of the first layer from the second reflected light; and,
removing noise data from the second preliminary data to obtain the second data.

5. The method of claim 1, wherein the first data is a map representing a positional coordinate in the vertical direction of the bottom surface of the first layer at each horizontal position of a plurality of horizontal positions, and
the second data is a map representing a positional coordinate in the vertical direction of the upper surface of the first layer at each of the horizontal positions.

6. The method of claim 5, wherein the skew data is a map representing the thickness of the first layer at each of the horizontal positions.

7. The method of claim 1, wherein the first layer is irradiated by each of the first and second lights in a scanning manner so as to irradiate an entire upper surface of the first layer.

8. The method of claim 1, wherein the first wavelength is in a range of 450 nm to 1050 nm, and the second wavelength is in a range of 100 nm to 400 nm.

9. The method of claim 1, wherein the first layer includes a photoresist layer.

10. The method of claim 1, wherein a
a pattern structure is disposed on the first substrate below the first layer,
a reflective layer covers an upper surface of the pattern structure, and
the first layer contacts an upper surface of the reflective layer.

11. The method of claim 10, wherein the reflective layer includes a material in which the first light is reflected from the upper surface of the reflective layer and is not transmitted into the reflective layer.

12. A method for measuring a thickness comprising:
forming a pattern structure on a sample substrate;
forming a reflective layer conformally on an upper surface of the pattern structure;
forming a photoresist layer on the reflective layer, the photoresist layer contacting the reflective layer;
irradiating the photoresist layer with first light that passes into the photoresist layer;
sensing first reflected light reflected from an upper surface of the reflective layer;
irradiating the photoresist layer with second light having a different wavelength from the first light onto the photoresist layer;
sensing second reflected light reflected from an upper surface of the photoresist layer;
obtaining first data representing a first positional coordinate in a vertical direction of a bottom surface of the photoresist layer for each horizontal position of a plurality of horizontal positions from the first reflected light;
obtaining second data representing a second positional coordinate in the vertical direction of the upper surface of the photoresist layer for each of the horizontal positions from the second reflected light; and,
obtaining skew data representing a thickness of the photoresist layer for each of the horizontal positions using the first and second data.

13. The method of claim 12, wherein obtaining the first data comprises:
obtaining raw data representing the first positional coordinate in the vertical direction of the bottom surface of the photoresist layer from the first reflected light; and
removing noise data from the raw data to obtain the first data.

14. The method of claim 12, wherein obtaining the second data comprises:
obtaining raw data representing the second positional coordinate in the vertical direction of the upper surface of the photoresist layer from the second reflected light; and
removing noise data from the raw data to obtain the second data.

15. The method of claim 12, wherein the photo resist layer is irradiated by each of the first and second lights in a scanning manner so as to irradiate an entire upper surface of the photoresist layer.

16. The method of claim 12, wherein a first wavelength of the first light is in a range of 450 nm to 1050 nm, and a second wavelength of the second light is in a range of 100 nm to 400 nm.

17. The method of claim 12, wherein a height of an upper surface of the pattern structure varies depending on horizontal positions thereof, and the reflective layer is formed to have a uniform thickness on the upper surface of the pattern structure.

18. The method of claim 12, wherein the reflective layer includes polysilicon or a metal.

19. A method for measuring a thickness comprising:
forming a pattern structure on a sample substrate, the pattern structure having varying heights of an upper surface depending on horizontal positions thereof;
forming a reflective layer conformally on an upper surface of the pattern structure;
forming a photoresist layer on the reflective layer, the photoresist layer contacting the reflective layer;
irradiating the photoresist layer with first light;
obtaining first data representing a position of a bottom surface of the photoresist layer from first reflected light, wherein the first reflected light is produced by the first light reflected from an upper surface of the reflective layer;
irradiating the photoresist layer with second light;
obtaining second data representing a position of an upper surface of the photoresist layer from second reflected light, wherein the second reflected light is produced by the second light reflected from an upper surface of the reflective layer; and
obtaining skew data representing a thickness of the photoresist layer using the first and second data.

20. The method of claim 19, wherein the skew data is a map representing the thickness of the photoresist layer at each horizontal position of a plurality of horizontal positions.
